(19) United States
(12) Patent Application Publication
(10) Pub. No.: US 2026/0223675 A1
(43) Pub. Date: Jul. 30, 2026

(54) THERMAL MANAGEMENT OF BASE DIES IN MULTICHIP COMPOSITE DEVICES

(71) Applicant: Intel Corporation, Santa Clara, CA (US)

(72) Inventors: Adel Elsherbini, Chandler, AZ (US); Wenhao Li, Chandler, AZ (US); Bhaskar Jyoti Krishnatreya, Hillsboro, OR (US); Debendra Mallik, Chandler, AZ (US); Krishna Vasanth Valavala, Chandler, AZ (US); Lei Jiang, Camas, WA (US); Yoshihiro Tomita, Tsukuba-shi (JP); Omkar Karhade, Chandler, AZ (US); Haris Khan Niazi, Scottsdale, AZ (US); Tushar Talukdar, Wilsonville, OR (US); Mohammad Enamul Kabir, Portland, OR (US); Xavier Brun, Hillsboro, OR (US); Feras Eid, Chandler, AZ (US)

(73) Assignee: Intel Corporation, Santa Clara, CA (US)

(21) Appl. No.: 19/578,262

(22) Filed: Mar. 25, 2026

Related U.S. Application Data
(63) Continuation of application No. 17/891,738, filed on Aug. 19, 2022.

(51) Int. Cl. H10W 40/40; G02B 6/42; H10W 40/28

(52) U.S. Cl. CPC H10W 40/40; G02B 6/4268; H10W 40/28

(57) ABSTRACT

Microelectronic devices, assemblies, and systems include a multichip composite device having one or more integrated circuit dies bonded to a base die and an inorganic dielectric material adjacent the integrated circuit dies and over the base die. The multichip composite device includes a dummy die, dummy vias, or integrated fluidic cooling channels laterally adjacent the integrated circuit dies to conduct heat from the base die.

### CROSS-REFERENCE TO RELATED APPLICATIONS

This application is a continuation of U.S. patent application Ser. No. 17/891,738, filed on Aug. 19, 2022, the entire contents of which is hereby incorporated by reference herein.

### BACKGROUND

As computing devices continue to get smaller and more powerful, thermal management presents new challenges. In particular, thermal management of multichip composite devices including a number of 3D stacked dies in a composite structure faces a number of challenges. Current architectures may include a handle die made of silicon that is bonded to active dies using a dielectric layer. Top dies of the 3D stacked dies are cooled via the handle silicon dies, which can then be attached to a lid. However, the base dies of the 3D architecture, on which the top dies or intermediary dies are stacked, are surrounded by dielectric fill materials with relatively low thermal conductivities, and the base dies may not have efficient thermal pathways. In some contexts, the base dies have high power densities, and current thermal solutions may not be sufficient causing, in turn, damage to the device or requiring throttling (reducing power), which negatively impacts performance. Therefore, there is a need to more efficiently remove heat from the active base dies of multichip composite devices.

It is with respect to these and other considerations that the present improvements have been needed. Such improvements may become critical as the desire to improve computing device performance and the corresponding necessity to remove heat from such devices becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a cross-sectional side view of a multichip composite device including a dummy die to provide a thermal pathway for heat removal from a base die;

FIG. 1B illustrates a cross-sectional plan view of the multichip composite device of FIG. 1A;

FIG. 2A illustrates a cross-sectional side view of a multichip composite device including a high thermal conductivity bonding layer to provide enhanced heat removal from a base die;

FIG. 2B illustrates a cross-sectional side view of a multichip composite device including a high thermal conductivity hybrid bonding layer to provide enhanced heat removal from a base die;

FIG. 3 illustrates a cross-sectional side view of a multichip composite device including a dummy die spanning multiple vertical levels of the multichip composite device to provide a thermal pathway for heat removal from a base die;

FIG. 4 illustrates a cross-sectional side view of a multichip composite device including a multilayer dummy die to provide a thermal pathway for heat removal from a base die;

FIG. 5 illustrates a cross-sectional side view of a multichip composite device including a multilayer dummy die spanning multiple vertical levels of the multichip composite device to provide a thermal pathway for heat removal from a base die;

FIG. 6 illustrates a cross-sectional side view of a multichip composite device including a thermoelectric cooling dummy die to provide cooling of a base die;

FIG. 7A illustrates a cross-sectional side view of a multichip composite device including dummy metal vias to provide a thermal pathway for heat removal from a base die;

FIG. 7B illustrates a simplified cross-sectional side view of a multichip composite device including handle die metal vias;

FIG. 8A illustrates a cross-sectional side view of a multichip composite device including dummy metal vias aligned to metal vias of a handle die to provide a thermal pathway for heat removal from a base die;

FIG. 8B illustrates exemplary alignments of dummy metal vias to metal vias of a handle die;

FIG. 9A illustrates a cross-sectional side view of a multichip composite device including plug type dummy metal vias to provide a thermal pathway for heat removal from a base die;

FIG. 9B illustrates an exemplary alignment of metal vias of handle die to a plug type dummy metal via;

FIG. 10 illustrates a cross-sectional side view of a multichip composite device including a dummy die having fluidic microchannels to provide heat removal from a base die;

FIG. 11 illustrates a cross-sectional side view of a multichip composite device including fluidic microchannels formed in a handle die and an inorganic dielectric material to provide heat removal from a base die;

FIG. 12 illustrates an example microelectronic device assembly including a heat removal enhancement;

FIG. 13 illustrates exemplary systems employing an IC assembly including a heat removal enhancement; and

FIG. 14 is a functional block diagram of an electronic computing device, all in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the term predominantly indicates the predominant constituent (i.e., greater than 50% is the constituent of greatest proportion in the layer or material). The term substantially pure indicates the constituent is not less than 99% of the material. The term pure indicates the constituent is not less than 99.5% of the material and the term completely pure indicates the constituent is not less than 99.9% of the material. As used herein, the terms “monolithic”, “monolithically integrated”, and similar terms indicate the components of the monolithic overall structure form an indivisible whole not reasonably capable of being separated.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. Additional terms are defined herein below.

As discussed, thermal management of multichip composite devices is a problem that, if not addressed, can cause damage to a device or undesirable device throttling. In some embodiments, a microelectronic device includes a multichip composite device that includes a base die and a number of integrated circuit (IC) dies attached to the base die. As used herein, the term microelectronic device indicates a device including one or more integrated circuits to provide one or more functions. The microelectronic device may be at any level such as a packaged device, an assembly, a motherboard, or a consumer product. The term multichip composite device indicates a device having a number of chips or dies that are integrated and formed into a quasi-monolithic structure. For example, a quasi-monolithic structure may have quasi-monolithic hierarchical integration of IC dies that couples base dies, IC dies or chiplets, and the like to form a composite structure of a processing system. Notably, the term composite indicates the structure has multiple components such as active dies, and dielectric material on and between the active dies.

Furthermore, a handle die or handle layer may be attached to the multichip composite device, and the handle die or handle layer may be part of the quasi-monolithic structure. As used herein the terms base die, integrated circuit dies, and chiplets indicate dies or chips having active circuitry (i.e., circuitry that is to provide electronic or device functionality when in operation). For example, the base die, integrated circuit dies, and chiplets may include processor circuitry, memory circuitry, control circuitry, signal and power routing circuitry, and so on. The term integrated circuit die may be used as an umbrella term with the term base die indicating an integrated circuit die deployed as a bottom or base layer die of the multichip composite device and the term chiplet deployed as a top or mid-level integrated circuit die of the multichip composite device. The terms handle die, handle layer, structural member, or structural element, as well as dummy die indicate structures that does not have such active circuitry. Instead, handle die, handle layer, structural member, or structural element, as well as dummy die are to provide mechanical support, thermal routing, and/or other functionality for the quasi-monolithic structure or microelectronic device. Notably, the dummy die may include active heat removal using thermoelectric cooling or fluidic cooling, however such structures do not provide active circuitry for the computational or memory function (i.e., performing arithmetic, data transfer, or the like) of the device.

In some embodiments, the multichip composite device includes one or more IC dies or chiplets bonded to a region of a surface (i.e., a top surface) of a base die. For example, the one or more IC dies or chiplets may be bonded to the surface of the base die using hybrid bonding. Hybrid bonding indicates bonding between surfaces that each include metallization (e.g., metal pads) interspersed with dielectric material. Bonds are formed between corresponding metallization and between corresponding dielectric material to form a wafer to wafer bond, die to wafer bond, or die to die bond. Such hybrid bonds may be performed using any techniques known in the art. In some embodiments, hybrid bonds include die-to-die interconnects with sub 10 micrometer pitch. Furthermore, the multichip composite device includes inorganic dielectric material laterally adjacent to the one or more IC dies or chiplets, over a region of the base die, and or laterally adjacent the base die. For example, the inorganic dielectric material may be formed over the hybrid bonded IC dies or chiplets and the base die to embed the IC dies or chiplets and the base die in the inorganic dielectric material. As used herein, the term inorganic dielectric material indicates materials not having carbon to hydrogen bonds and being characterized as an electrical insulator. For example, an inorganic dielectric material may have a resistivity comparable to that of silicon dioxide. Although carbon may not be a foundational component of the inorganic dielectric material, the inorganic dielectric material may include carbon as, for example, a dopant.

A thermal solution or cooling device is provided lateral to the IC dies or chiplets and on a region of the base die. The thermal solution is to remove heat from the base die and to offer an a more efficient thermal pathway for heat generated by the base die. Such structures and devices discussed herein offer cooling options for thermal management of base dies in a 3D architecture such as a multichip composite device. Such devices and structures include one or a combination of dummy dies having a greater thermal conductivity than the inorganic dielectric, dummy dies including a high thermal conductivity heat transfer layer and a bulk material layer, a dummy die having a thermoelectric cooling device therein, high conductivity metal within the inorganic dielectric, high conductivity metal plugs, and/or heat removal fluid microchannels. The thermal solutions discussed herein between the base dies and handle die provide optimized thermal pathways to improve heat transfer from the base die to the thermal solution on top of the stack (i.e., over the handle die), resulting in lower temperatures in the base die and/or higher operation power capability.

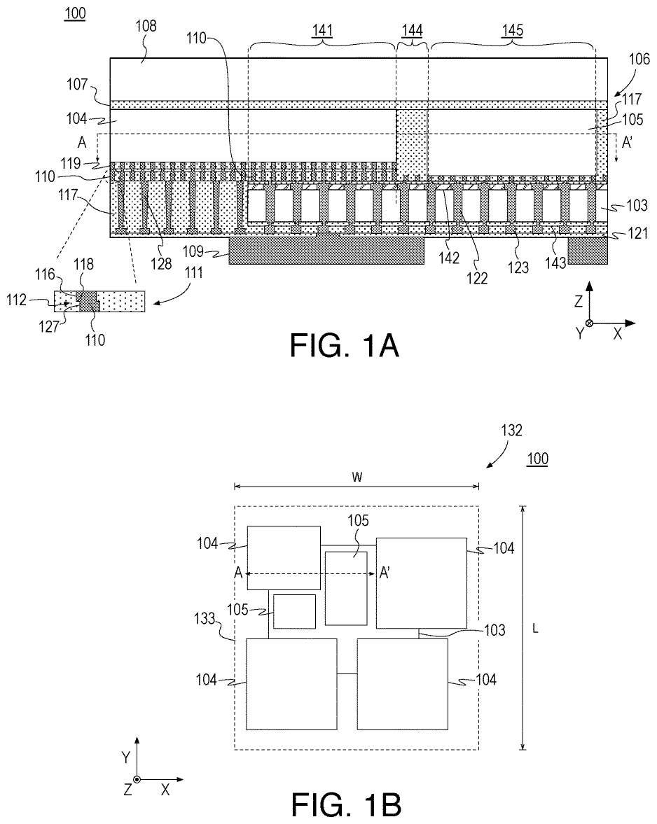

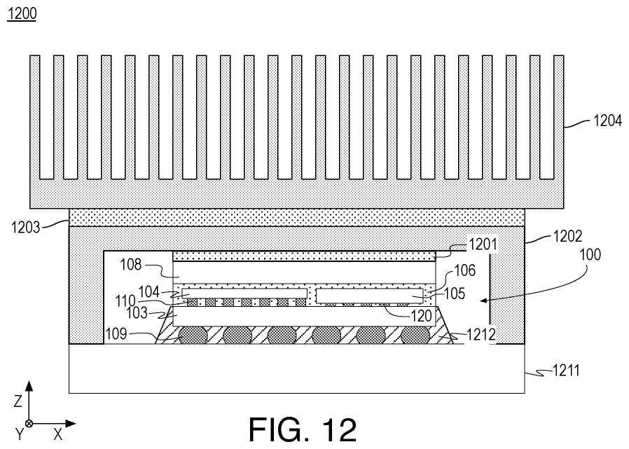

FIG. 1A illustrates a cross-sectional side view of a multichip composite device 100 including a dummy die 105 to provide a thermal pathway for heat removal from a base die 103, arranged in accordance with some embodiments. For example, multichip composite device 100 may be deployed in any microelectronic device. FIG. 1B illustrates a cross-sectional plan view providing an expanded view taken at plane A-A′ in FIG. 1A. As shown in FIG. 1A, multichip composite device 100 includes any number of IC dies 104 (which may be characterized as chiplets) coupled to a surface 142 of a base die 103. In some embodiments, base die 103 includes through vias 122 (e.g., through silicon vias, TSVs). As discussed, the terms IC die and chiplet indicate an active circuitry device (i.e., circuitry that is to provide computational functionality when in operation). For example, an IC die or chiplet may contain circuitry to perform a defined subset of functionality such as a memory chip, microprocessor, microcontroller, commodity IC (e.g., chip used for repetitive processing routines, simple tasks, application specific IC, etc.). The term base die also indicates an active circuitry device and may also be characterized as an IC die. For example, IC dies such as chiplets and base dies may be individual dies connected together to create the functionalities of a monolithic IC. As shown, base die 103 is at a lowest or base layer of multichip composite device 100. Furthermore, base die 103 is to interconnect, via interconnects 109 to a substrate (not shown). For example, interconnects 109 may be package level interconnects formed through a dielectric layer 121 to couple to a package substrate such as a package substrate, as discussed further herein below with respect to FIG. 12. As shown, interconnects 109 are adjacent a second surface 143 of base die 103 such that surface 143 is opposite surface 142. Interconnects 109 may be solder bumps or balls, interconnect posts or pads, interconnects formed from a conductive film or conductive paste, or the like.

IC dies 104 may be bonded to surface 142 of base die 103 using any suitable technique or techniques such as hybrid bonding to form die level interconnects 110. For example, die level metallization 119 may route to die level interconnects 110. In some embodiments, surfaces including metallization are interspersed among dielectric material may be formed on each of IC dies 104 and surface 142 of base die 103. In some embodiments, the patterning of the surfaces matches metal to metal and dielectric to dielectric for hybrid bonding between IC dies 104 and base die 103. Such surface may then be brought together optionally under pressure and/or heat to meld the metal to form die level interconnects 110 and, optionally, to meld the dielectric material to form the hybrid bond. As shown with respect to enlarged view 111, in some embodiments, die level interconnects 110 may include a misalignment 112 indicative of the hybrid bond. Misalignment 112 may include, for example, a first sidewall 116 misaligned with a second sidewall 127 such that a lateral offset 118 (i.e., measured in the x-dimension) is therebetween. In some embodiments, lateral offset 118 is in the range of 10 to 200 nm. For example, lateral offset 118 may be not less than 10 nm, not less than 25 nm, or not less than 50 nm. Although any thicknesses may be used, in some embodiments, base die 103 may have a thickness between 75 and 150 microns. In some embodiments, base die 103 has a thickness between 50 and 80 microns. In some embodiments, base die 103 has a thickness of about 100 microns. In some embodiments, IC dies 104 have thicknesses between 20 and 50 microns. In some embodiments, IC dies 104 have thicknesses of not more than 50 microns, with thicknesses in the range of 20 to 30 microns being advantageous. As shown, dummy dies 105 have a similar thickness to that of IC dies 104.

IC dies 104 and base die 103 may include any suitable substrates and device components inclusive of semiconductor dies having a device layer and metallization layers fabricated using known semiconductor manufacturing processes. In some embodiments, the substrate is a substantially monocrystalline semiconductor, such as silicon, germanium, however other material systems may be deployed. The device layer may include any suitable devices such as transistors, capacitors, resistors, etc. As shown in FIG. 1A, an inorganic dielectric material 106 is filled in between IC dies 104, on exposed portions of base die 103 and, optionally, over IC dies 104 and dummy dies 105. In the illustrated example, inorganic dielectric material 106 includes a bulk portion 117 laterally adjacent base die 103 and laterally adjacent IC dies 104 and dummy dies 105 and a bonding layer 107 over IC dies 104 and dummy dies 105. As shown, in some embodiments, through vias 128 may extend through one or more levels of bulk portion 117 of inorganic dielectric material 106. Bulk portion 117 and bonding layer 107 may be the same materials or they may be different. For example, an inorganic dielectric material may be partially removed (i.e., polished back) to provide bulk portion 117 and to expose top surfaces 208, 209 of IC dies 104 and dummy dies 105. In such examples, another layer may be formed over the exposed top surfaces 208, 209 to provide a bonding layer. In some embodiments, the bonding layer may be used for increased thermal performance as discussed herein below. Inorganic dielectric material 106 may be any suitable inorganic dielectric material such as silicon dioxide. Notably, the thin IC dies 104 at least partially enable the use of such advantageous inorganic dielectric materials.

Handle die 108 is bonded to the top of multichip composite device 100 using bonding layer 107 or another bonding layer as discussed herein. Handle die 108 may be characterized as a structural member, structural element, structural silicon (when silicon is deployed), or the like. For example, such terms are used interchangeably herein. The term handle die is largely used for the sake of clarity herein. Handle die 108 provides mechanical robustness during processing, packaging, and so on, and handle die 108 aids in heat spreading and heat removal from IC dies 104 and base die 103 to a thermal solution, which is illustrated herein below.

As shown, multichip composite device 100 includes IC die 104 connected, for example using hybrid bonding, to a first region 141 of surface 142 of base die 103. As discussed, surface 143, opposite surface 142 is to interconnect to a substrate such as a package substrate, motherboard, interposer, or the like. Multichip composite device 100 further includes inorganic dielectric material 106 laterally adjacent IC die 104 and over a second region 144 of base die 103, and dummy die 105 coupled to a third region 145 of base die 103 and laterally adjacent IC die 104. Notably, dummy die 105 has a greater thermal conductivity than inorganic dielectric material 106 for an improved thermal pathway from the portion of base die 103. As used herein, the term laterally adjacent indicates that an x-y plane intersects the two components that are laterally adjacent. As shown, in some embodiments, top surfaces 208, 209 of IC dies 104 and dummy dies 105 are substantially co-planar. For example, in any of the embodiments herein, metal may be plated on IC dies 104 and dummy dies 105 to provide the same z-height, and the metal may be optionally planarized. The metal may then be bonded to handle die 108 using metal to metal direct bonding, for example, for an improved thermal pathway. Alternatively, dielectrics with comparable-to-better thermal conductivity than silicon dioxide may be used to achieve co-planarity and to subsequently bond to handle die 108 via fusion bonding. Furthermore, the term thermal conductivity is used in accordance with its common usage as the measure of an object or materials ability to conduct heat.

As shown in FIG. 1B, where inorganic dielectric material 106 is not shown for the sake of clarity of presentation, IC dies 104 and dummy dies 105 may be arrayed over base die 103 in any suitable configuration to form a complex 132 having an area defined by edges 133 thereof. For example, complex 132 may have an area defined by a width W and a length L. In some embodiments, IC dies 104 and dummy dies 105 are arranged entirely within the defined area such that no edge of IC dies 104 and dummy dies 105 extends beyond edges 133 of complex 132. In some embodiments, handle die 108 substantially shares the area (W×L) and defines complex 132. In some embodiments, base die 103 also shares the area (W×L) such that edges of handle die 108 and the edges of base die 103 are substantially vertically aligned. For example, fabrication of base die 103 and handle die 108 may be performed at the wafer level (with IC dies 104 attached to the base die wafer using die to wafer attachment), and the overall structure may be diced such that shared edges between base die 103 and handle die 108 are formed (i.e., such that their outer edges are vertically aligned).

Returning to FIG. 1A, dummy dies 105 may be placed on and over base die 103 in locations where IC dies 104 are absent for improved thermal conductivity pathways. Any number of dummy dies 105 may be deployed on base die 103 such as one, two, three to ten, or more. Dummy dies 105 are or include materials having a larger thermal conductivity than that of inorganic dielectric material 106, which may be, for example, silicon dioxide (e.g., thermal conductivity of about 1.3 W/m-K). In some embodiments, dummy dies 105 include or are a material that has a thermal conductivity of not less than 50 times, 100 times, or 200 times that of inorganic dielectric material 106. In some embodiments, one or more of dummy dies 105 are crystalline silicon having a thermal conductivity of about 120 W/m-K. Use of crystalline silicon offers advantages such as a large increase in thermal conductivity, ease of use, and others. However, dummy dies 105 may include any suitable high thermal conductivity material(s).

In some embodiments, one or more of dummy dies 105 includes silicon and carbon (e.g., silicon carbide). In some embodiments, one or more of dummy dies 105 is a composite of silicon carbide and diamond. In some embodiments, one or more of dummy dies 105 a composite of silicon and diamond. In some embodiments, one or more of dummy dies 105 is a composite of silicon and copper (i.e., in the form of thermal copper vias extending through silicon dies). In some embodiments, one or more of dummy dies 105 is sapphire (e.g., a composite of aluminum and oxygen, aluminum oxide). In some embodiments, one or more of dummy dies 105 is mica (i.e., any silicate material having the formula B2-3(X, Si)4O10(O, F, OH)2). In some embodiments, one or more of dummy dies 105 includes gallium and nitrogen (e.g., gallium nitride). In some embodiments, one or more of dummy dies 105 includes silicon, diamond, a composite of silicon and carbon, a composite of silicon and diamond, or a composite of silicon and copper. Each of dummy dies 105 may use the same material or structures, or they may be different. In some embodiments, dummy dies 105 include a high thermal conductivity layer on a bulk substrate material as discussed herein below.

In some embodiments, thermal management may be further enhanced by forming a bonding interface between dummy dies 105 to base die 103 and/or between handle die 108 and dummy dies 105 that is a fusion bond using a thin dielectric layer or a hybrid bonding layer. For example, the thin dielectric layer may have a sub-micron thickness silicon dioxide, silicon nitride, silicon carbon-nitride, or the like. In addition or in the alternative, the bonding layer may be hybrid bonding with high thermal conductivity metal vias such as copper to copper coupling. Such bonding techniques are illustrated and discussed with respect to the interface between handle die 108 and dummy dies 105 herein below; however, such bonding may be provided in addition or in the alternative with respect to the bond between dummy dies 105 to base die 103 in an analogous manner.

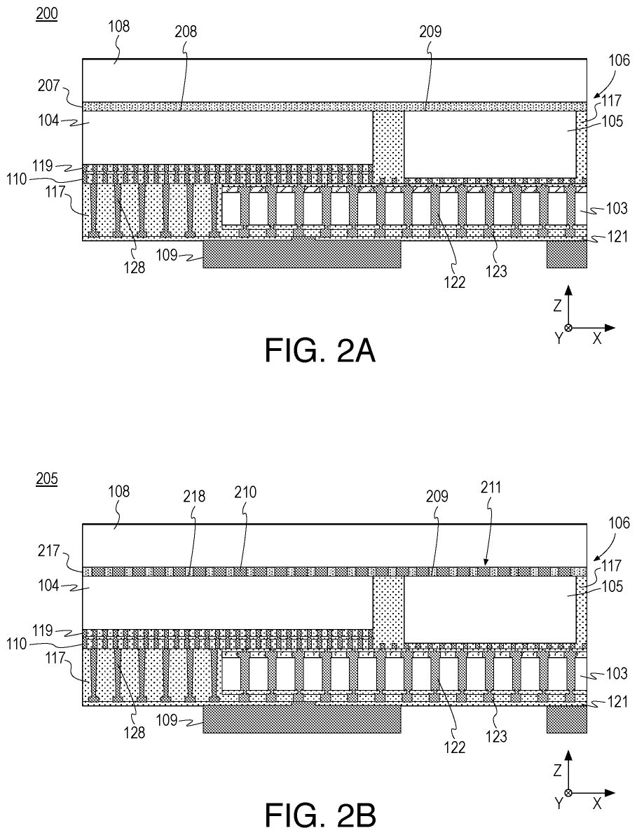

FIG. 2A illustrates a cross-sectional side view of a multichip composite device 200 including a high thermal conductivity bonding layer 207 to provide enhanced heat removal from base die 103, arranged in accordance with some embodiments. As shown, multichip composite device 200 includes similar components and structures with respect to multichip composite device 100 with the exception that bonding layer 107 is replaced with bonding layer 207. In FIG. 2A, and elsewhere herein, like numerals indicate like components, which may include any characteristics discussed throughout. As discussed, the bond between dummy die 105 and base die 103 may also be replaced with a bonding layer having the same characteristics discussed with respect to bonding layer 207.

In some embodiments, bulk portion 117 of inorganic dielectric material 106 has a first thermal conductivity that is less than a thermal conductivity of bonding layer 207. In some embodiments, bulk portion 117 is silicon dioxide and bonding layer 207 is a different, higher thermal conductivity inorganic dielectric material. In some embodiments, bonding layer 207 is or includes silicon and nitrogen (i.e., a compound including silicon and nitrogen, silicon nitride). In some embodiments, bonding layer 207 is or includes silicon nitride having a thermal conductivity of not less than 10 W/m-K. In some embodiments, bonding layer 207 is or includes silicon and carbon (i.e., a compound including silicon and carbon, silicon carbide). In some embodiments, bonding layer 207 is or includes silicon carbide having a thermal conductivity of not less than 245 W/m-K. In some embodiments, bonding layer 207 is or includes silicon, carbon, and nitrogen (i.e., a compound including silicon, carbon, and nitrogen, silicon carbon-nitride). In some embodiments, bonding layer 207 is or includes silicon carbon-nitride having a thermal conductivity of not less than 7 W/m-K. In some embodiments, bonding layer 207 provides a relatively thin interface. In some embodiments, bonding layer 207 has a thickness of not more than 1 micron. In some embodiments, has a thickness of not more than 750 nm. In some embodiments, has a thickness of not more than 500 nm. As shown, in some embodiments, top surfaces 208, 209 of IC dies 104 and dummy dies 105 are substantially co-planar, and bonding layer 207 extends over the top surfaces 208, 209 of IC dies 104 and dummy dies 105.

FIG. 2B illustrates a cross-sectional side view of a multichip composite device 205 including a high thermal conductivity hybrid bonding layer 217 to provide enhanced heat removal from base die 103, arranged in accordance with some embodiments. As shown, multichip composite device 205 includes similar components and structures with respect to multichip composite device 200 with the exception that bonding layer 207 is replaced with bonding layer 217, which includes a hybrid bonding interface. As discussed, the bond between dummy die 105 and base die 103 may also be replaced with a bonding layer having the same characteristics discussed with respect to bonding layer 217.

As shown, bonding layer 217 includes a hybrid bonding interface including metal vias 210 interspersed in dielectric material 218. Dielectric material may be any suitable inorganic dielectric discussed herein such as silicon dioxide, silicon nitride, silicon carbide, or silicon carbon-nitride. Metal vias 210 may be any suitable metal such as copper. In some embodiments, metal pads are patterned within a dielectric material on both handle die 108 and a top surface defined by the top surfaces 208, 209 of IC dies 104 and dummy dies 105 (e.g., at the wafer processing level) such that the metal pads and dielectric material have a co-planar surface. The surfaces may then be brought together to form the hybrid bonding layer 217. Bonding layer 217 may have any suitable thickness such as a thickness of not more than 750 nm. In some embodiments, bonding layer 207 has a thickness of not more than 1 micron, not more than 750 nm, or not more than 500 nm. As shown, in some embodiments, bonding layer 217 extends over substantially co-planar top surfaces 208, 209 of IC dies 104 and dummy dies 105.

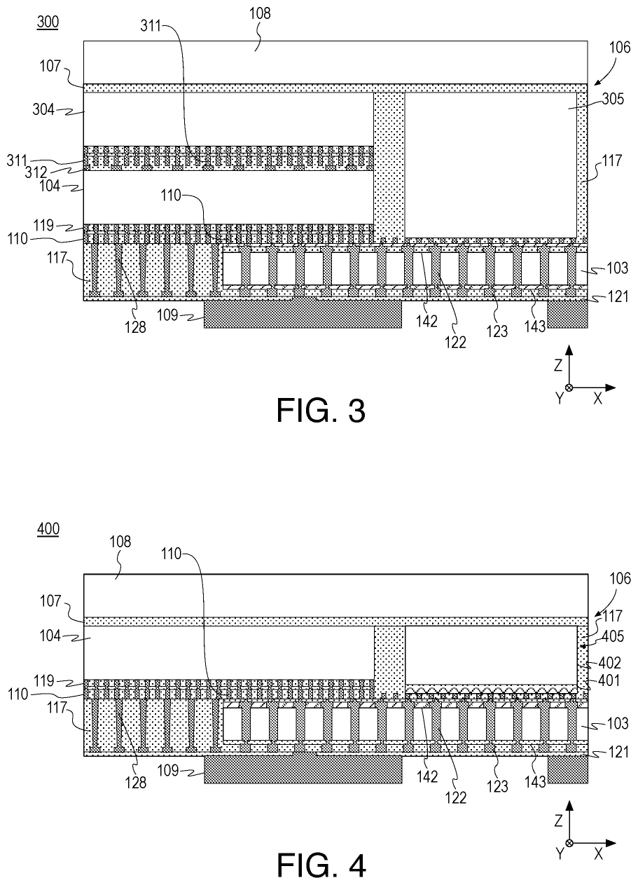

FIG. 3 illustrates a cross-sectional side view of a multichip composite device 300 including a dummy die 305 spanning multiple vertical levels of multichip composite device 300 to provide a thermal pathway for heat removal from base die 103, arranged in accordance with some embodiments. As shown, multichip composite device 300 includes similar components and structures with respect to multichip composite device 100 with the exception that multiple levels of IC dies 104, 304 are implemented in multichip composite device 300.

As discussed, IC die 104 may be bonded to surface 142 of base die 103 using any suitable technique or techniques such as hybrid bonding to form die level interconnects 110. In a similar manner, IC die 304 may be bonded to a top surface of IC die 104 using any suitable technique or techniques such as hybrid bonding to form die level interconnects 311. For example, die level interconnects 311 may be formed over landing pads 312. As shown, in some embodiments, IC die 304 may share a footprint with IC die 104. In other embodiments, IC die 304 is coupled to region of IC die 104 and a dummy die or any other heat removal structure discussed herein may be deployed laterally adjacent 304.

One or more dummy dies 305 may again be placed on and over base die 103 in locations where IC dies 104 are absent for improved thermal conductivity pathways. In the context of multichip composite device 300, dummy dies 305 have an increased height to vertically span across the combined heights of IC dies 104, 304 and the corresponding interconnects. In some embodiments, IC die 304 is hybrid bonded to IC die 104 opposite IC die 104 from base die 103. In some embodiments, a thickness of dummy die 305 is not less than a sum of a thickness of IC die 104 and a thickness of IC die 304. For example, a thickness of dummy die 305 may be equal to a sum of the thicknesses of IC die 104, IC die 304 and the bonding interfaces between IC die 104 and base die 103 and between IC die 304 and IC die 104. In some embodiments, top surfaces of IC die 304 and dummy die 305 are substantially co-planar. Although illustrated with respect to bonding layer 107, any bonding layer such as those discussed with respect to FIGS. 2A and 2B may be deployed in multichip composite device 300.

Any number of dummy dies 305 and/or dummy dies 105 (i.e., mounted on a top surface of IC die 104) may be deployed in multichip composite device 300. Dummy dies 305 are or include materials having a larger thermal conductivity than that of inorganic dielectric material 106, which may be, for example, silicon dioxide. For example, dummy dies 305 may include any materials discussed with respect to dummy dies 105 such as crystalline silicon, silicon carbide, diamond, a composite of silicon carbide and diamond, a composite of silicon and diamond, a composite of silicon and copper (i.e., in the form of thermal copper vias extending through silicon dies), or others. Each of dummy dies 305 may use the same material or structures, or they may be different. In some embodiments, one or more of dummy dies 305 is or includes at least one material that is more thermally conductive than crystalline silicon such as crystalline or polycrystalline diamond, copper through vias, boron nitride, boron arsenide, or aluminum nitride. Such materials may be used as an entirety of one or more of dummy dies 305 or they may be deployed as a layer or layers of one or more of dummy dies 305.

Although illustrated with respect to a three-layer multichip composite device 300 inclusive of a base die layer (i.e., a zeroth layer), a first IC die or chiplet layer, and a second IC die or chiplet layer, any number of layers such as four, five or more may be deployed. In such contexts, the pertinent dummy die has a thickness not less than a sum of thicknesses of the first through Nth IC dies. As shown, handle die 108 is bonded to bonding layer 107 (or another bonding layer as discussed herein) at a top of multichip composite device 300. Handle die 108 provides mechanical robustness during processing, packaging, and so on, and handle die 108 aids in heat spreading and heat removal. For example, handle die 108 may be coupled to an integrated heat spreader, heat pump, heat sink, or other thermal solution as discussed herein.

As discussed, in some examples, a dummy die may include a high thermal conductivity material. In some contexts, a high thermal conductivity may be deployed adjacent base die 103 such that the high thermal conductivity is formed on a bulk material or bulk material layer of the base die.

FIG. 4 illustrates a cross-sectional side view of a multichip composite device 400 including a multilayer dummy die 405 provide a thermal pathway for heat removal from base die 103, arranged in accordance with some embodiments. As shown, multichip composite device 400 includes similar components and structures with respect to multichip composite device 100 with the exception that multilayer dummy die 405 is deployed in multichip composite device 400.

As discussed, heat removal from base die 103 may be improved by replacing inorganic dielectric material 106 with multilayer dummy die 405 In the context of multichip composite device 400, multilayer dummy die 405 is deployed to advantageously provide a heat transfer layer 401 having a high thermal conductivity at or near surface 142 of base die 103, such that heat transfer layer having is on a substrate layer 402. For example, substrate layer 402 may be characterized as a bulk material layer, a substrate, or a carrier and substrate layer 402 may provide support for heat transfer layer 401. In some embodiments, substrate layer 402 is crystalline silicon. However, substrate layer 402 may be any material or materials discussed with respect to dummy dies 105. For example, heat transfer layer 401 is on substrate layer 402 such that heat transfer layer 401 is adjacent base die 103, heat transfer layer 401 has a thickness less than a thickness of substrate layer 402, and heat transfer layer 401 has a thermal conductivity greater than a thermal conductivity of substrate layer 402.

A relatively thin heat transfer layer 401 may be formed on substrate layer 402. Due to the high thermal conductivity of heat transfer layer 401, a relatively thin layer may be deployed. In some embodiments, heat transfer layer 401 has a thickness in the range of 100 nm to 5 microns. In some embodiments, heat transfer layer 401 has a thickness of not more than 5 microns, not more than 3 microns, or not more than 1 micron. Heat transfer layer 401 may include any material or materials having a greater thermal conductivity that that substrate layer 402. In some embodiments, the material or composite of materials of heat transfer layer 401 has a thermal conductivity of not less than twice the thermal conductivity of substrate layer 402. In some embodiments, the material or composite of materials of heat transfer layer 401 has a thermal conductivity of not less than five times the thermal conductivity of substrate layer 402. In some embodiments, the material or composite of materials of heat transfer layer 401 has a thermal conductivity of not less than seven times the thermal conductivity of substrate layer 402.

As discussed, in some embodiments, substrate layer 402 is crystalline silicon, having a thermal conductivity of about 120 W/m-K. In some embodiments, heat transfer layer 401 is or includes crystalline or polycrystalline diamond. In some embodiments, heat transfer layer 401 is or includes crystalline or polycrystalline diamond having a thermal conductivity of not less than 400 W/m-K. In some embodiments, heat transfer layer 401 is or includes crystalline or polycrystalline diamond having a thermal conductivity of not less than 1,000 W/m-K. In some embodiments, heat transfer layer 401 is or includes copper. In some embodiments, heat transfer layer 401 is or includes copper having a thermal conductivity of not less than 300 W/m-K. In some embodiments, heat transfer layer 401 is or includes boron and nitrogen (i.e., a compound including boron and nitrogen, boron nitride). In some embodiments, heat transfer layer 401 is or includes boron and nitrogen having a thermal conductivity of not less than 375 W/m-K. In some embodiments, heat transfer layer 401 is or includes boron and arsenic (i.e., a compound including boron and arsenic, boron arsenide). In some embodiments, heat transfer layer 401 is or includes boron and arsenic having a thermal conductivity of not less than 650 W/m-K. In some embodiments, heat transfer layer 401 is or includes silicon and carbon (i.e., a compound including silicon and carbon, silicon carbide). In some embodiments, heat transfer layer 401 is or includes silicon and carbon having a thermal conductivity of not less than 245 W/m-K. In some embodiments, heat transfer layer 401 is or includes aluminum and nitrogen (i.e., a compound including aluminum and nitrogen, aluminum nitride). In some embodiments, heat transfer layer 401 is or includes aluminum and nitrogen having a thermal conductivity of not less than 160 W/m-K. In some embodiments, heat transfer layer 401 includes a combination of two or more of such materials. Other high thermal conductivity material layers may be used.

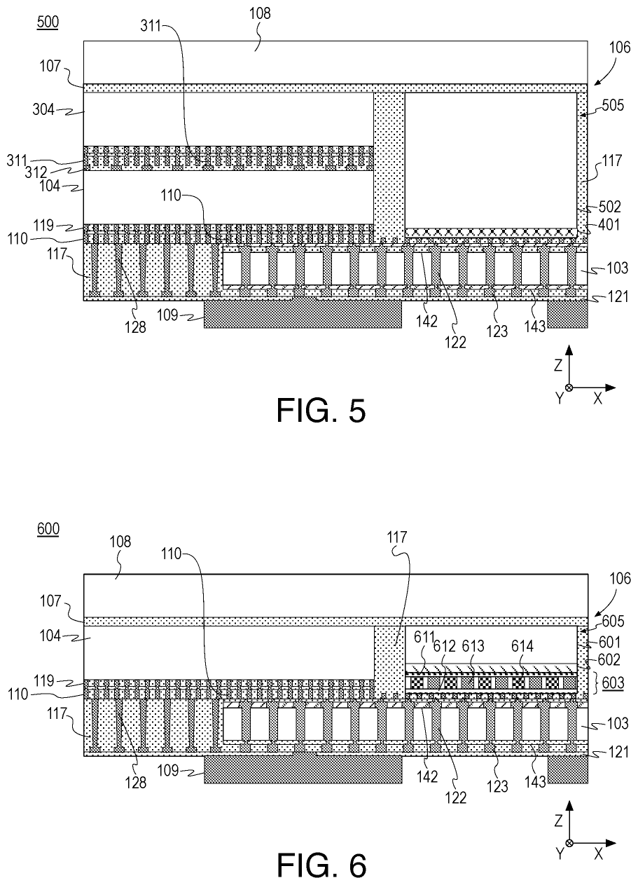

FIG. 5 illustrates a cross-sectional side view of a multichip composite device 500 including a multilayer dummy die 505 spanning multiple vertical levels of multichip composite device 500 to provide a thermal pathway for heat removal from base die 103, arranged in accordance with some embodiments. As shown, multichip composite device 500 includes similar components and structures with respect to multichip composite device 300 with the exception that that multilayer dummy die 405 in multichip composite device 500.

IC die 104 is bonded to surface 142 of base die 103 and IC die 304 is bonded to a top surface of IC die 104. Both interfaces may be bonded via hybrid bonding, for example. One or more multilayer dummy dies 505 are placed on and over base die 103 for improved thermal conductivity. In the context of multichip composite device 500, multilayer dummy dies 505 include heat transfer layer 401 and an increased height of substrate layer 502 to vertically span across the combined heights of IC dies 104, 304 and the corresponding interconnects. In some embodiments, a thickness of multilayer dummy dies 505 (i.e., a sum of the thicknesses of heat transfer layer 401 and substrate layer 502) is not less than a sum of a thickness of IC die 104 and a thickness of IC die 304. For example, a thickness of multilayer dummy dies 505 may be equal to a sum of the thicknesses of IC die 104, IC die 304 and the bonding interfaces between IC die 104 and base die 103 and IC die 304 and IC die 104. As shown, top surfaces of IC die 304 and multilayer dummy dies 505 maybe substantially co-planar and bonding layer 107 (or any other bonding layer discussed herein) extends across the top surfaces.

In the context of multilayer dummy die 505, heat transfer layer 401 may have any characteristics discussed with respect to FIG. 4 and substrate layer 502 may deploy any materials discussed with respect to substrate layer 402. Furthermore, multilayer dummy die 505, in terms of deployment within multilayer dummy die 505 may have any characteristics discussed with respect to dummy dies 305. For example, multilayer dummy die 505 may include a layer of diamond, copper, boron nitride, boron arsenide, silicon carbide, aluminum nitride, or a multilayer stack of such materials on a silicon substrate or another substrate material discussed herein.

Although illustrated with respect to a three-layer multichip composite device 500, any number of layers such as four, five or more may be deployed. Furthermore, handle die 108 is bonded to bonding layer 107 (or another bonding layer as discussed herein) at a top of multichip composite device 500. Handle die 108, in turn, may be coupled to an integrated heat spreader, heat pump, heat sink, or other thermal solution as discussed herein.

FIG. 6 illustrates a cross-sectional side view of a multichip composite device 600 including a thermoelectric cooling dummy die 605 to provide cooling of base die 103, arranged in accordance with some embodiments. As shown, multichip composite device 600 includes similar components and structures with respect to multichip composite device 100 with the exception that thermoelectric cooling dummy die 605 is deployed in multichip composite device 600. As discussed, thermoelectric cooling dummy die 605, although including a cooling circuit, is absent electronic components or circuitry to provide computational functionality to multichip composite device 600.

In some embodiments, a thermoelectric cooling device 603 is formed on a substrate layer 601. Substrate layer 601 may include any material or materials discussed with respect to dummy die 105 or substrate layer 402. As shown, thermoelectric cooling device 603 faces base die 103 and removes heat from base die 103. In some embodiments, base die 103 includes a photonic element adjacent thermoelectric cooling device 603. As used herein the term photonic element indicates any device or structure that generates, detects, or manipulates (e.g., by emission, transmission, modulation, signal processing, switching, or amplification) light (e.g., photons). In some embodiments, the photonic element is a lasing cavity. For example, such photonic elements may need to be maintained within a particular temperature range, which may be provided by thermoelectric cooling device 603.

In some embodiments, the thickness of thermoelectric cooling device 603 may be minimized using thin film thermoelectric as known in the art. In some embodiments, thermoelectric cooling device 603 has a thickness of not more than 20 microns. In some embodiments, thermoelectric cooling device 603 has a thickness of not more than 15 microns. In some embodiments, thermoelectric cooling device 603 has a thickness of not more than 10 microns. Thermoelectric cooling device 603 may operate under the Peltier effect. In some embodiments, thermoelectric cooling device 603 includes two plates 611, 612, such as ceramic plates, separated by an array of alternating p-type semiconductor materials 613 and n-type semiconductor materials 614. For example, solid solutions of bismuth telluride, antimony telluride, or bismuth selenide may be deployed in p-type semiconductor materials 613 and n-type semiconductor materials 614.

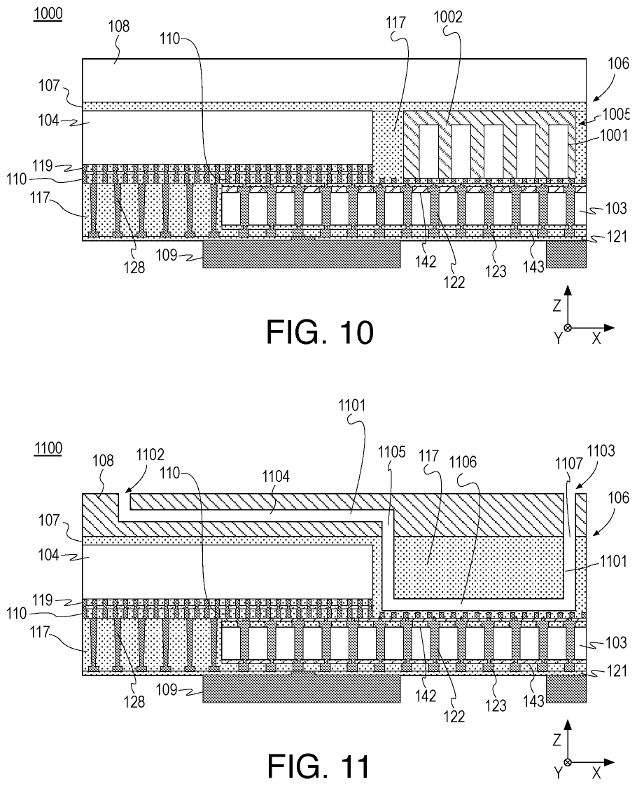

Thermoelectric cooling device 603 may be powered using any suitable technique or techniques. In some embodiments, thermoelectric cooling device 603 is powered directly by through vias 122 of base die 103. Thermoelectric cooling device 603 collects heat from base die 103 and rejects it toward substrate layer 601. The rejected heat may be transferred through substrate layer 601 to handle die 108, and to a thermal solution as discussed herein below with respect to FIG. 12. In some embodiments, the rejected heat is removed using liquid microchannels as discussed herein below with respect to FIGS. 10 and 11.

In some embodiments, a phase change material 602 is provided between thermoelectric cooling device 603 and substrate layer 601 to anchor the rejected heat. As used herein, the term phase change material indicates a material that can release and absorb sufficient energy at a phase transition to provide heat or cooling. For example, phase change material 602 may include a paraffin, a salt hydrate, a solid/solid phase change material, or the like.

Although illustrated with respect to thermoelectric cooling device 603 being on substrate layer 601, in some embodiments, thermoelectric cooling device 603 is an entirety of dummy die 605. For example, plates 611, 612 may be directly on and bonded to base die 103 and handle die 108 or bonding layer 107 and substrate layer 601 and/or phase change material 602 may not be deployed. In multichip composite device 600, thermoelectric cooling dummy die 605 is deployed to advantageously provide thermoelectric cooling device 603 having high thermal conductivity and cooling capability at or near surface 142 of base die 103, such that thermoelectric cooling device 603 is adjacent base die 103. As discussed, base die 103 may include a photonic element immediately below thermoelectric cooling device 603.

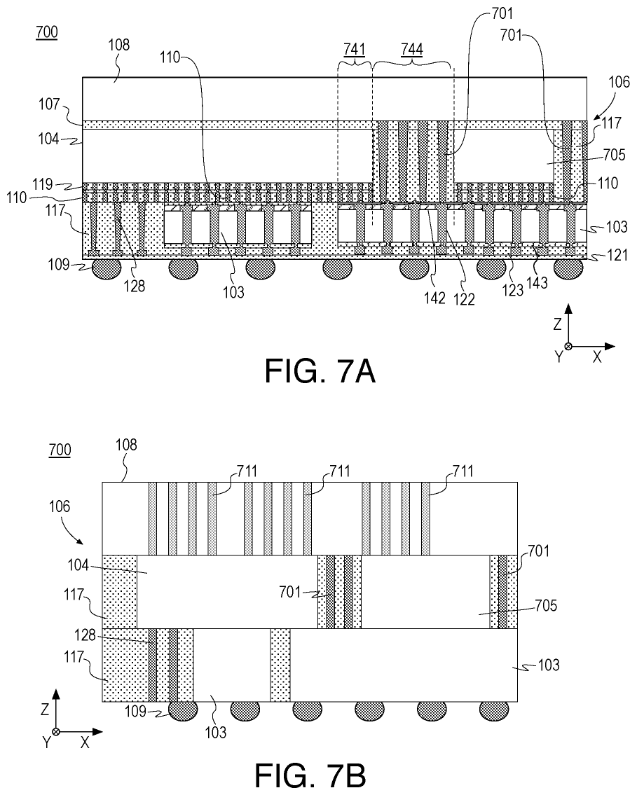

FIG. 7A illustrates a cross-sectional side view of a multichip composite device 700 including dummy metal vias 701 to provide a thermal pathway for heat removal from base die 103, arranged in accordance with some embodiments. Multichip composite device 700 includes any number of IC dies 104 coupled to surface 142 of base die 103 in region 741. In the context of multichip composite device 700, die 705 may be an active IC die (as shown) or die 705 may deploy any thermal dummy die discussed herein. As shown, base die 103 is at a lowest or base layer of multichip composite device 700 and base die 103 is to interconnect, via interconnects 109 to a substrate (not shown). Multichip composite device 700 also illustrates a multichip composite device may include any number of base dies at a base level of the multichip composite device 700. IC dies 104 are bonded to surface 142 using any suitable technique or techniques such as hybrid bonding, as discussed herein, to form die level interconnects 110.

IC dies 104 and base die 103 may include any suitable substrates and device components discussed herein, and inorganic dielectric material 106 may be filled in between IC dies 104, dies 705, on exposed portions of base die 103 and, optionally, over IC dies 104 and dies 705. Handle die 108 is bonded to the top of multichip composite device 700 using bonding layer 107 (or other bonding layer), and handle die 108 provides mechanical support and heat removal.

As shown, multichip composite device 700 includes IC die 104 connected, for example using hybrid bonding, to a first region 741 of surface 142 of base die 103. As discussed, surface 143, opposite surface 142, is to interconnect to a substrate such as a package substrate, motherboard, interposer, or the like. Multichip composite device 700 further includes inorganic dielectric material 106 laterally adjacent IC die 104 and over a second region 744 of base die 103, and die 705 coupled to a third region (not labeled) of base die 103 and laterally adjacent IC die 104. Furthermore, multichip composite device 700 includes one or more dummy metal vias 701 in contact with region 744 of base die 103 and in contact with handle die 108. In some embodiments, dummy metal vias 701 may be characterized as through dielectric vias (TDVs). Dummy metal vias 701 have a greater thermal conductivity than inorganic dielectric material 106 for an improved thermal pathway from the pertinent portion of base die 103. The term dummy metal via indicates a structure that does provide active routing of power or signal for multichip composite device 700. Instead, dummy metal vias are to provide thermal routing for the quasi-monolithic structure or microelectronic device.

As discussed above with respect to FIG. 1B, IC dies 104, dies 705 and dummy metal vias 701 may be arrayed over base die 103 in any suitable configuration to form a complex similar to complex 132. As shown in FIG. 7A, dummy metal vias 701 may be placed on and over base die 103 in locations where IC dies 104 are absent for improved thermal conductivity. Any number and density of dummy metal vias 701 may be deployed on base die 103. In some embodiments, dummy metal vias 701 have a cross sectional diameter in the range of 500 nm to 5 microns.

Dummy metal vias 701 are or include metals having a larger thermal conductivity than that of inorganic dielectric material 106, which may be, for example, silicon dioxide. In some embodiments, dummy metal vias 701 include or are a material that has a thermal conductivity of not less than 50 times, 100 times, or 200 times that of inorganic dielectric material 106. In some embodiments, dummy metal vias 701 are copper. However, other metals such as aluminum, tungsten, gold, or others may be used. In some embodiments, dummy metal vias 701 include a liner layer or layers on inorganic dielectric material 106 to provide adhesion or barrier protection. In some embodiments, dummy metal vias 701 include copper within a tantalum, tantalum nitride, titanium, titanium nitride, or silicon nitride liner layer. In some embodiments, dummy metal vias 701 may also contain non-metal fillers (e.g., diamonds and ceramics), for coefficient of thermal expansion (CTE) management. For example, such filler materials may bring the average CTE of the via closer to that of dielectric 106.

As with the dummy dies discussed herein, dummy metal vias 701 may be provided over known or expected hot spots of base die 103 to provide an efficient thermal pathway from the hot spot to handle die 108. In some embodiments, base die 103 includes thermal vias provided by through vias 122. For example, through vias 122 may be TSVs plated with copper to improve thermal pathways to dummy metal vias 701.

FIG. 7B illustrates a simplified cross-sectional side view of multichip composite device 700 including handle die metal vias 711, arranged in accordance with some embodiments. FIG. 7B illustrates handle die 108 may include metal vias 711. Metal vias 711 may improve the thermal conduction of multichip composite device 700. Metal vias 711 have a greater thermal conductivity than the bulk material of handle die 108 (e.g., crystalline silicon) for improved thermal pathways Any number and density of metal vias 711 may be deployed in handle die 711. In some embodiments, metal vias 711 have a cross sectional diameter in the range of 500 nm to 5 microns. In some embodiments, the cross sectional diameter of metal vias 711 is greater than that of dummy metal vias 701. Metal vias 711 may include any material or materials discussed with respect to dummy metal vias 701. For example, metal vias 711 may include copper.

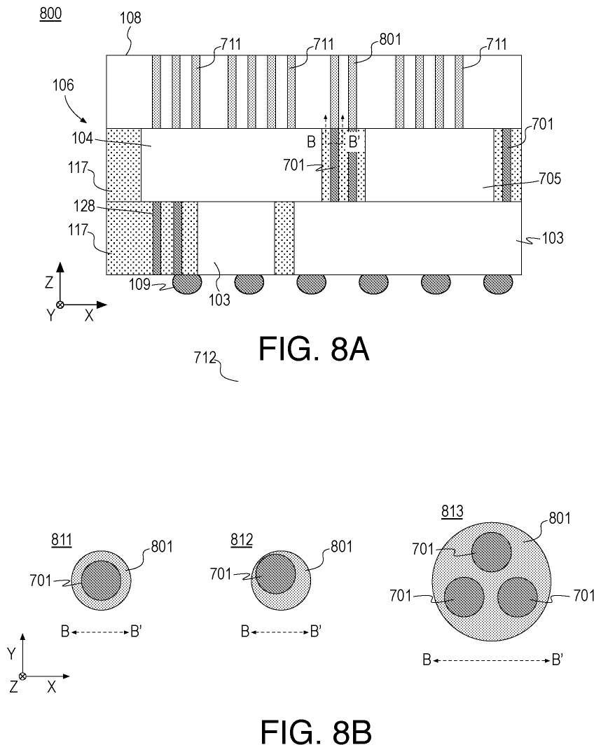

FIG. 8A illustrates a cross-sectional side view of a multichip composite device 800 including dummy metal vias 701 aligned to metal vias 711 of handle die 108 to provide a thermal pathway for heat removal from base die 103, arranged in accordance with some embodiments. For example, dummy metal vias 701 are aligned with metal vias 801. Multichip composite device 800 includes similar components and structures with respect to multichip composite device 700 with the exception that dummy metal vias 701 are aligned to and in contact with metal vias 711. As discussed herein heat may be transferred through handle die 108 to a thermal solution such as an integrated heat spreader, heat sink, heat pipe, etc. By aligning and contacting dummy metal vias 701 and metal vias 711, hot spots of base die 103 can be vertically aligned to a thermal pathway inclusive of one or more of dummy metal vias 701 and one or more of metal vias 801. In the context of FIG. 8A, dummy metal vias 701 and metal vias 801 may be fully aligned such that they share a cross sectional shape and size.

FIG. 8B illustrates exemplary alignments 811, 812, 813 of dummy metal vias 701 to metal vias 801 of handle die 108, arranged in accordance with some embodiments. For example, dummy metal vias 701 may contact metal vias 801 in any suitable manner. In the context of alignment 811, a one-to-one contact is made such that dummy metal via 701 has a smaller diameter than metal via 801, and dummy metal via 701 and metal via 801 are substantially aligned. For example, dummy metal via 701 and metal via 801 may share a centerline extending in the z-direction (into and out of the page). Although illustrated with dummy metal via 701 having a smaller diameter than metal via 801, in some embodiments, dummy metal via 701 has a larger diameter than metal via 801, or their diameters may be the same.

As shown with respect to alignment 812, in some embodiments, dummy metal via 701 and metal via 801 may be misaligned or offset. For example, routing or other concerns may necessitate an offset of, for example 100 to 500 nm or more. In alignment 812, and dummy metal via 701 is again illustrated as having a smaller diameter than metal via 801. However, dummy metal via 701 may have a larger diameter than metal via 801, or their diameters may be about the same. Furthermore, in alignment 812, although offset, dummy metal via 701 is fully within metal via 801. In some embodiments, dummy metal via 701 may extend outside of metal via 801 and overlap onto a bulk substrate portion of handle die 108.

As shown with respect to alignment 813, in some embodiments, multiple dummy metal vias 701 may contact a shared metal via 801. Any number of dummy metal vias 701 may contact a shared metal via 801 such as two, three, five, or more. Such multiple dummy metal vias 701 may be arrayed in any manner on shared metal via 801. Alternatively, in some embodiments, multiple metal vias 801 may contact a single shared dummy metal via 701.

As discussed, by aligning and contacting dummy metal vias 701 and metal vias 801, efficient thermal conductivity from base die 103 and, in particular, from hot spots of base die 103 is achieved. In addition or in the alternative, a high thermal conductivity inorganic dielectric material 106 may be deployed. For example, inorganic dielectric material 106 may include a material having a higher thermal conductivity than silicon dioxide such as silicon nitride (e.g., a compounding including silicon and nitrogen) and/or aluminum nitride (e.g., a compounding including aluminum and nitrogen). Other high thermal conductivity inorganic dielectric material(s), as discussed herein, may be implemented.

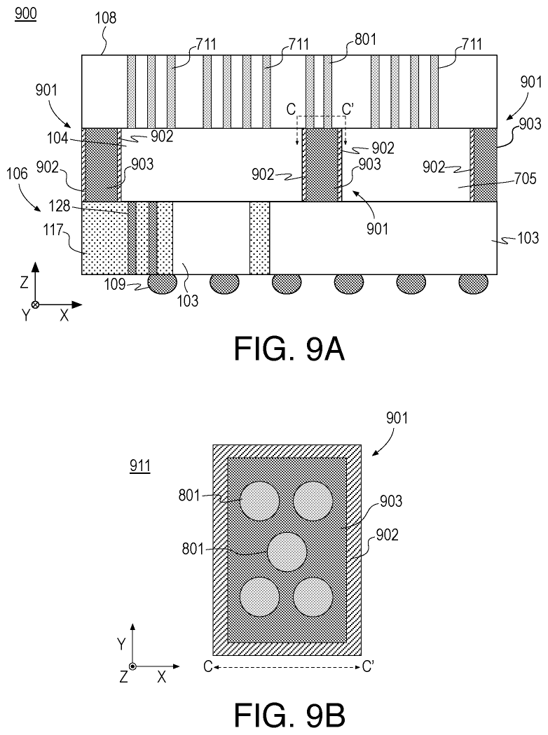

FIG. 9A illustrates a cross-sectional side view of a multichip composite device 900 including plug type dummy metal vias 901 to provide a thermal pathway for heat removal from base die 103, arranged in accordance with some embodiments. Multichip composite device 900 includes any number of IC dies 104 coupled to base die 103, which is at a lowest or base layer of multichip composite device 700 and base die 103 is to interconnect, via interconnects 109 to a substrate (not shown). Inorganic dielectric material 106 may be filled adjacent base dies 103 and, in some embodiments in between IC dies 104, dies 705, on exposed portions of base die 103 and, optionally, over IC dies 104 and dies 705 (not show in FIG. 9A). Handle die 108 is bonded to the top of multichip composite device 900 as discussed herein.

Multichip composite device 900 includes IC die 104 connected, for example using hybrid bonding, to base die 103 and inorganic dielectric material 106 laterally adjacent at least base dies 103 and optionally laterally adjacent IC die 104. Multichip composite device 900 includes one or more dummy metal vias 901. In the example of FIG. 9A, dummy metal vias 901 each include a liner layer 902 and a fill metal 903. In some embodiments, liner layer 902 provides adhesion or barrier protection. Liner layer 902 may be a single metal layer or a multilayer stack. In some embodiments, dummy metal vias 901 include copper fill metal 903 within a tantalum, tantalum nitride, titanium, titanium nitride, or silicon nitride liner layer 902. However, other material systems may be used. In some embodiments, dummy metal vias 901 include a single metal material and liner layer 920 is not deployed.

As shown, each of dummy metal vias 901 extends laterally between adjacent sidewalls of IC dies 104 and dies 705. For example, dies 705 may be active IC dies. Furthermore, each of dummy metal vias 901 extends vertically between base die 103 and handle die 108, between inorganic dielectric material 106 (e.g., bulk portion of inorganic dielectric material 106) and handle die 108, and/or through vias 128 and handle die 108. For example, dummy metal vias 901, which may be characterized as metal plugs, metal layers, or metal fill, may be provided at a level or levels above the level of base dies 103 to extend vertically from top surfaces of base dies 103 (or materials co-planar with top surfaces of base dies 103) to handle die 108. In some embodiments, one of dummy metal vias 901 is in contact with a sidewall of IC die 105. In some embodiments, one of dummy metal vias 901 includes liner layer 902 in contact with the sidewall and of IC die 105 and fill metal 903 within liner layer 902.

Dummy metal vias 901 may include any material or materials discussed with respect to dummy metal vias 701. Dummy metal vias 701 have a greater thermal conductivity than inorganic dielectric material 106 for an improved thermal pathway from the pertinent portion of base die 103 to handle die 108. As shown with respect to FIG. 9A, the gap between IC dies 104 and dies 705 may be filled by plating, for example, with high conductivity metal (e.g., copper) in place of inorganic dielectric material, with the high conductivity metal (i.e., fill metal 903) surrounded by a relatively thick liner layer 902. In some embodiments, after deposition (e.g., plating) of these thermally enhanced gap fill non-dielectric material and optional planarization, bonding dielectrics and metal may be deposited above IC dies 104 and dies 705 for optional hybrid bonding to handle die 108, as discussed with respect to FIG. 2B.

FIG. 9B illustrates an exemplary alignment 911 of metal vias 801 of handle die 108 to a plug type dummy metal via 901, arranged in accordance with some embodiments. For example, dummy metal vias 901 may contact metal vias 801 in any suitable manner. In the context of alignment 911, a multiple-to-one contact is made such that metal vias 801 have a smaller lateral dimension (e.g., diameter) than dummy metal via 901. Any number of metal vias 801 may land on each region of fill metal 903 such as two, three, five, or more.

FIG. 10 illustrates a cross-sectional side view of a multichip composite device 1000 including a dummy die 1005 having fluidic microchannels 1001 to provide heat removal from base die 103, arranged in accordance with some embodiments. Multichip composite device 1000 includes any number of IC dies 104 coupled to surface 142 of base die 103, as discussed herein. IC dies 104 are bonded to surface 142 using any suitable technique or techniques such as hybrid bonding to form die level interconnects 110. As shown, inorganic dielectric material 106 may be filled in between IC dies 104 and dummy die 1005, on portions of base die 103 and, optionally, over IC dies 104 and dummy die 1005. Handle die 108 is bonded to the top of multichip composite device 1000 using bonding layer 107 (or other bonding layer).

As shown, multichip composite device 1000 includes IC die 104 connected, for example using hybrid bonding, to a first region of surface 142 of base die 103 and dummy die 1005 bonded to a second region of surface 142 of base die 103. Surface 143, opposite surface 142, is to interconnect to a substrate such as a package substrate, motherboard, interposer, or the like. Multichip composite device 1000 further includes inorganic dielectric material 106 laterally adjacent IC die 104 and dummy die 1005, and over a third region of base die 103.

In the context of multichip composite device 1000, dummy die 1005 includes fluidic microchannels 1001 to provide heat removal from base die 103. In the example of FIG. 10, dummy die 1005 includes any number of microchannels 1001 for flow of a cooling fluid (not shown) therein. For example, microchannels 1001 may extend laterally across surface 142 of base die 103. Also, as shown, microchannels 1001 extend (vertically) between surfaces of IC dies 104, 114, 115 and a pertinent portion 409 of handle die 403. That is, each of microchannels 1001 provides an opening such that the opening is at least partially enclosed by surface 142 and an enclosure of dummy die 1005.

The term microchannels indicates a channel to convey a heat transfer fluid with the multiple microchannels providing discrete separate channels or a network of channels. Notably, the plural microchannels does not indicate separate discrete channels are deployed. Such microchannels 1005 may be provided in any pattern in the x-y plane such as patterns of multiple parallel microchannels (as shown), serpentine patterns, networks of branching microchannels, or the like. Microchannels 1005 couple to a heat exchanger (not shown) that removes heat from and cools the heat transfer fluid before re-introduction to microchannels 1005. The flow of fluid within microchannels 1005 may be provided by a pump or other fluid flow device. The operation of the heat exchanger, pump, etc. may be controlled by a controller.

Microchannels 1005 may have any suitable dimensions. In some embodiments, microchannels 1005 have a width (in the x-dimension) of not less than 2 microns, not less than 5 microns, or not less than 10 microns. In some embodiments, microchannels 1005 have a height (in the y-dimension) of not less than 2 microns, not less than 5 microns, or not less than 10 microns. The heat transfer fluid deployed in microchannels 1005 may be single phase (liquid or gas) or multi-phase (liquid and gas), and may include any suitable material. In some embodiments, the heat transfer fluid is a water, dielectric refrigerant, or other coolant. In some embodiments, microchannels 1005 are etched into dummy die 1005 and dummy die 1005 is flip-bonded to base die 103. Dummy die may be any material discussed with respect to dummy die 105. In some embodiments, dummy die 1005 is at least partially formed of crystalline silicon.

FIG. 11 illustrates a cross-sectional side view of a multichip composite device 1100 including fluidic microchannels 1101 formed in handle die 108 and inorganic dielectric material 106 to provide heat removal from base die 103, arranged in accordance with some embodiments. Multichip composite device 1100 includes any number of IC dies 104 coupled to surface 142 of base die 103, as discussed herein. IC dies 104 are bonded to surface 142 using any suitable technique or techniques such as hybrid bonding to form die level interconnects 110. As shown, inorganic dielectric material 106 may be filled in between IC dies 104 and dummy die 1005, on portions of base die 103 and, optionally, over IC dies 104 and dummy die 1005. Handle die 108 is bonded to the top of multichip composite device 1000 using bonding layer 107 (or other bonding layer).

As shown, multichip composite device 1100 includes IC die 104 connected, for example using hybrid bonding, to a first region of surface 142 of base die 103. Surface 143, opposite surface 142, is to interconnect to a substrate such as a package substrate, motherboard, interposer, or the like. Multichip composite device 1100 further includes inorganic dielectric material 106 laterally adjacent IC die 104 and dummy die 1005, and over a third region of base die 103. One or more microchannels 1101 are formed in handle die 108 and inorganic dielectric material 106 such that at least a lateral portion 1106 of microchannels 1101 are over a second region of surface 142 of base die 103.

As shown, fluidic microchannels 1101 may include inlet and outlet ports 1102, 1103 in handle die 108, a lateral portion 1104 extending through handle die 108, a vertical portion 1105 extending from handle die 108 and into inorganic dielectric material 106, a lateral portion 1106 extending through inorganic dielectric material 106, and a vertical portion extending from inorganic dielectric material 106 into handle die 1107, and to port 1103. However, microchannels 1101 may be formed in any suitable pattern. In some embodiments, with reference to FIG. 3, multichip composite device 1100 includes a second IC die 304 hybrid bonded to IC die 104 and opposite IC die 104 from base die 103. In such embodiments, microchannels may extend across the combined thickness of IC die 304 and IC die 104. In some embodiments, a height of a first of the microchannels extends vertically from at least a bottom of IC die 104 beyond a bottom of IC die 304. Such a microchannels configuration may be deployed in the context of multichip composite device 1100 or multichip composite device 1000.

Microchannels 1101 may have any characteristics discussed with respect to microchannels 1005. For example, microchannels 1101 may be provided in any pattern in the x-y plane such as patterns of multiple parallel microchannels, serpentine patterns, networks of branching microchannels, or the like. Microchannels 1101 may couple to a heat exchanger to removes heat from the heat transfer fluid, and the flow of fluid within microchannels 1101 may be provided by a pump or other fluid flow device, which may be controlled by a controller.

The heat removal enhancement structures discussed herein may be used alone or in any combination to remove heat from base die 103. For example, the discussed dummy dies, multi-layer spanning dummy dies, heat removal bonding layers, dummy dies having a heat transfer layer, dummy vias, plug type dummy vias, thermoelectric coolers, and fluidic microchannels may be deployed in any combination to provide heat removal enhancement in a multichip composite device.

FIG. 12 illustrates an example microelectronic device assembly 1200 including a heat removal enhancement, in accordance with some embodiments. In the illustrative example of FIG. 12, multichip composite device 100 is represented. However, any multichip composite device, microelectronic device, or the like discussed herein may be deployed in microelectronic device assembly 1200. As shown, microelectronic device assembly 1200 includes base die 103 attached to a substrate 1211 via interconnects 109, and an optional underfill 1212. As discussed, IC dies 104 are bonded to base die 103 by interconnects 110, and inorganic dielectric material 106 is provided adjacent IC dies 104. In the context of FIG. 12, multichip composite device 100 also includes dummy die 105 and handle die 108; however other heat removal enhancement discussed herein may be used in the context of microelectronic device assembly 1200. Microelectronic device assembly 1200 may include a power supply (not shown) coupled to one or more of base die 103, IC dies 104, or other components of microelectronic device assembly 1200. The power supply may include a battery, voltage converter, power supply circuitry, or the like.

Microelectronic device assembly 1200 further includes a thermal interface material (TIM) 1201 disposed on a top surface of handle die 108. TIM 1201 may include any suitable thermal interface material and may be characterized as TIM 1. Integrated heat spreader 1202 having a surface on TIM 1201 extends over multichip composite device 100, and is mounted to substrate 1211. Substrate 1211 may include any suitable substrate such as a package substrate, motherboard, interposer, or the like. In addition or in the alternative, substrate 1211 may be mounted to a motherboard. Microelectronic device assembly 1200 further includes TIM 1203 disposed on a top surface of integrated heat spreader 1202. TIM 1203 may include any suitable thermal interface material and may be characterized as TIM 2. TIM 1201 and TIM 1203 may be the same materials or they may be different. Heat sink 1204 (e.g., an exemplary heat dissipation device or thermal solution) is on TIM 1203 and dissipates heat generated by base die 103. Although illustrated with respect to microelectronic device assembly 1200, the various heat removal enhancements discussed herein may be deployed in any suitable architecture and form factor. For example, microelectronic device assembly 1200 may be used in desktop and server form factors. In other contexts, a heat solution such as a heat pipe or heat spreader may be mounted directly on TIM 1201. Such assemblies may be used in smaller form factor devices. Other heat dissipation devices may be used in concert with the heat removal enhancement structures discussed herein.

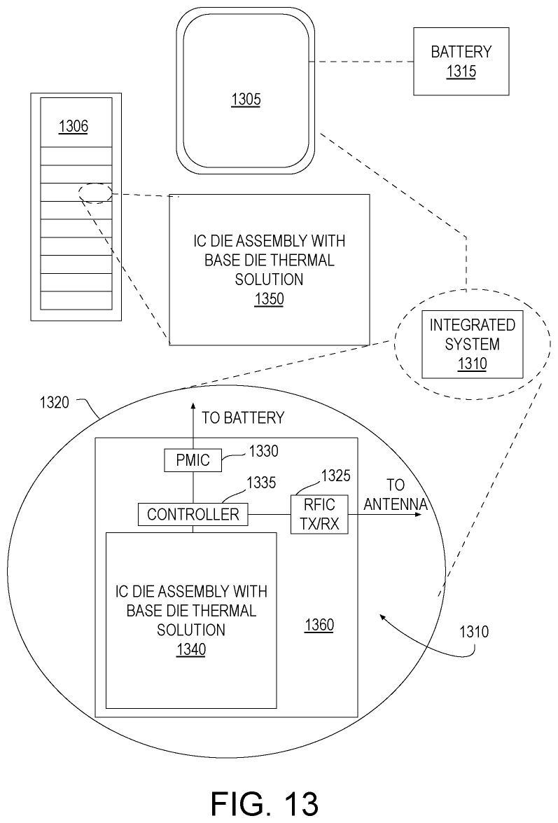

FIG. 13 illustrates exemplary systems employing an IC assembly including a heat removal enhancement, in accordance with some embodiments. The system may be a mobile computing platform 1305 and/or a data server machine 1306, for example. Either may employ a component assembly including at least heat removal enhancement as described elsewhere herein. Server machine 1306 may be any commercial server, for example including any number of high-performance computing platforms disposed within a rack and networked together for electronic data processing, which in the exemplary embodiment includes an IC die assembly 1350 with a heat removal enhancement as described elsewhere herein. Mobile computing platform 1305 may be any portable device configured for each of electronic data display, electronic data processing, wireless electronic data transmission, or the like. For example, mobile computing platform 1305 may be any of a tablet, a smart phone, a laptop computer, etc., and may include a display screen (e.g., a capacitive, inductive, resistive, or optical touchscreen), a chip-level or package-level integrated system 1310, and a battery 1315. Although illustrated with respect to mobile computing platform 1305, in other examples, chip-level or package-level integrated system 1310 and a battery 1315 may be implemented in a desktop computing platform, an automotive computing platform, an internet of things platform, or the like. As discussed below, in some examples, the disclosed systems may include a sub-system 1360 such as a system on a chip (SOC) or an integrated system of multiple ICs, which is illustrated with respect to mobile computing platform 1305.

Whether disposed within integrated system 1310 illustrated in expanded view 1320 or as a stand-alone packaged device within data server machine 1306, sub-system 1360 may include memory circuitry and/or processor circuitry 1340 (e.g., RAM, a microprocessor, a multi-core microprocessor, graphics processor, etc.), a power management integrated circuit (PMIC) 1330, a controller 1335, and a radio frequency integrated circuit (RFIC) 1325 (e.g., including a wideband RF transmitter and/or receiver (TX/RX)). As shown, one or more IC dice, such as memory circuitry and/or processor circuitry 1340 may be assembled and implemented such that one or more have a heat removal enhancement as described herein. In some embodiments, RFIC 1325 includes a digital baseband and an analog front end module further comprising a power amplifier on a transmit path and a low noise amplifier on a receive path). Functionally, PMIC 1330 may perform battery power regulation, DC-to-DC conversion, etc., and so has an input coupled to battery 1315, and an output providing a current supply to other functional modules. As further illustrated in FIG. 13, in the exemplary embodiment, RFIC 1325 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1340 may provide memory functionality for sub-system 1360, high level control, data processing and the like for sub-system 1360. In alternative implementations, each of the SOC modules may be integrated onto separate ICs coupled to a package substrate, interposer, or board.

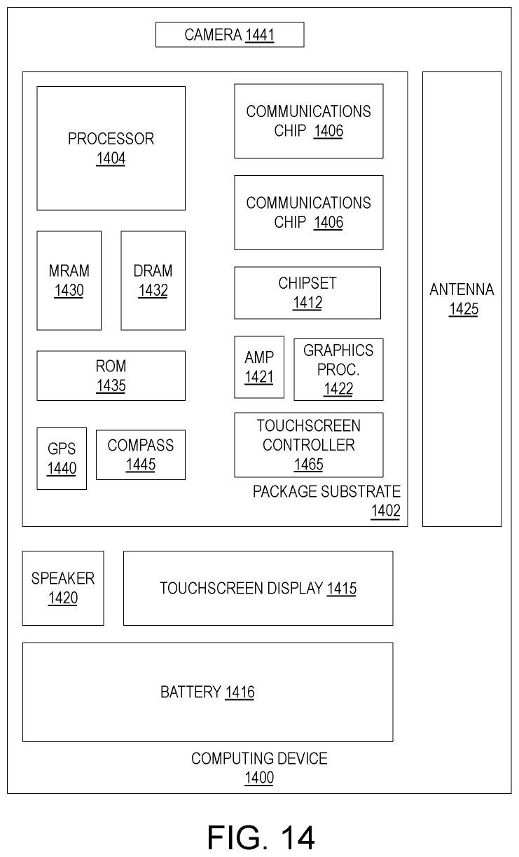

FIG. 14 is a functional block diagram of an electronic computing device 1400, in accordance with some embodiments. For example, device 1400 may, via any suitable component therein, employ heat removal enhancement (i.e., thermal enhancement) in accordance with any embodiments described elsewhere herein. Device 1400 further includes a motherboard or package substrate 1402 hosting a number of components, such as, but not limited to, a processor 1404 (e.g., an applications processor). Processor 1404 may be physically and/or electrically coupled to package substrate 1402. In some examples, processor 1404 is within an IC assembly that includes a heat removal enhancement as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1406 may also be physically and/or electrically coupled to the package substrate 1402. In further implementations, communication chips 1406 may be part of processor 1404. Depending on its applications, computing device 1400 may include other components that may or may not be physically and electrically coupled to package substrate 1402. These other components include, but are not limited to, volatile memory (e.g., DRAM 1432), non-volatile memory (e.g., ROM 1435), flash memory (e.g., NAND or NOR), magnetic memory (MRAM 1430), a graphics processor 1422, a digital signal processor, a crypto processor, a chipset 1412, an antenna 1425, touchscreen display 1415, touchscreen controller 1465, battery 1416, audio codec, video codec, power amplifier 1421, global positioning system (GPS) device 1440, compass 1445, accelerometer, gyroscope, speaker 1420, camera 1441, and mass storage device (such as hard disk drive, solid-state drive (SSD), compact disk (CD), digital versatile disk (DVD), and so forth, or the like.

Communication chips 1406 may enable wireless communications for the transfer of data to and from the computing device 1400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1406 may implement any of a number of wireless standards or protocols, including, but not limited to, those described elsewhere herein. As discussed, computing device 1400 may include a plurality of communication chips 1406. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

The following pertain to exemplary embodiments.

In one or more first embodiments, a multichip composite device comprises an integrated circuit die hybrid bonded to a first region of a first surface of a base die, wherein a second surface of the base die, opposite the first surface, is to interconnect to a substrate, an inorganic dielectric material laterally adjacent the integrated circuit die and over a second region of the first surface of the base die, and a dummy die coupled to a third region of the first surface of the base die and laterally adjacent the integrated circuit die, wherein the dummy die comprises a greater thermal conductivity than the inorganic dielectric material.

In one or more second embodiments, further to the first embodiments, the dummy die comprises one of silicon, diamond, a compound of silicon and carbon, a composite of silicon and diamond, or a composite of silicon and copper.

In one or more third embodiments, further to the first or second embodiments, the multichip composite device further comprises a structural member over the dummy die and a bonding layer between the structural member and the dummy die, wherein the bonding layer has a thickness of not more than 1 micron and the bonding layer comprises silicon and one of oxygen, nitrogen, or carbon.

In one or more fourth embodiments, further to the first through third embodiments, the bonding layer further comprises metal vias, and wherein the structural member is hybrid bonded to the dummy die.

In one or more fifth embodiments, further to the first through fourth embodiments, top surfaces of the integrated circuit die and the dummy die are substantially co-planar and the bonding layer extends over the top surfaces of the integrated circuit die and the dummy die.

In one or more sixth embodiments, further to the first through fifth embodiments, the multichip composite device further comprises a second integrated circuit die hybrid bonded to the integrated circuit die and opposite the integrated circuit die from the base die, wherein a thickness of the dummy die is not less than a sum of a thickness of the integrated circuit die and a thickness of the second integrated circuit die.

In one or more seventh embodiments, further to the first through sixth embodiments, the dummy die comprises a substrate layer and a heat transfer layer on the substrate layer, wherein the heat transfer layer is adjacent the base die, the heat transfer layer having a thickness less than the substrate layer and a thermal conductivity greater than the substrate layer.

In one or more eighth embodiments, further to the first through seventh embodiments, the bulk material layer comprises silicon and the heat transfer layer comprises one of diamond, copper, a compound of boron and nitrogen, a composite of boron and arsenic, a compound of silicon and carbon, or a compound of aluminum and nitrogen.

In one or more ninth embodiments, further to the first through eighth embodiments, the dummy die comprises a thermoelectric cooling device adjacent the base die.

In one or more tenth embodiments, further to the first through ninth embodiments, the base die comprises a photonic element.

In one or more eleventh embodiments, further to the first through tenth embodiments, the dummy die comprises one of a phase change material or one or more microchannels to allow flow of a cooling fluid therein adjacent the thermoelectric cooling device.

In one or more twelfth embodiments, a multichip composite device comprises an integrated circuit die hybrid bonded to a first region of a first surface of a base die, wherein a second surface of the base die, opposite the first surface, is to interconnect to a substrate, an inorganic dielectric material laterally adjacent at least one of the integrated circuit or the base die, a structural member over the integrated circuit die and opposite the integrated circuit die from the base die, and a dummy metal via in contact with a second region of the first surface of the base die and in contact with the structural member.

In one or more thirteenth embodiments, further to the twelfth embodiments, the dummy metal via comprises a through dielectric via extending through the inorganic dielectric material.

In one or more fourteenth embodiments, further to the twelfth or thirteenth embodiments, the structural member comprises a plurality of through vias, at least one of the through vias in contact and vertically aligned with the dummy metal via.

In one or more fifteenth embodiments, further to the twelfth through fourteenth embodiments, the dummy metal via is in contact with a sidewall of the integrated circuit die.

In one or more sixteenth embodiments, further to the twelfth through fifteenth embodiments, the dummy metal via comprises a liner layer in contact with the sidewall and a fill metal within the liner layer.

In one or more seventeenth embodiments, further to the twelfth through sixteenth embodiments, the inorganic dielectric material comprises nitrogen and one of silicon or aluminum.

In one or more eighteenth embodiments, a multichip composite device comprises an integrated circuit die hybrid bonded to a first region of a first surface of a base die, wherein a second surface of the base die, opposite the first surface, is to interconnect to a substrate, an inorganic dielectric material laterally adjacent the integrated circuit die and over a second region of the first surface of the base die, and one or more microchannels laterally adjacent the integrated circuit die and over a second region of the first surface of the base die, the microchannels to allow flow of a cooling fluid therein.

In one or more nineteenth embodiments, further to the eighteenth embodiments, the one or more microchannels are within a dummy die adjacent the integrated circuit die.

In one or more twentieth embodiments, further to the eighteenth or nineteenth embodiments, at least a first of the microchannels extends laterally within the inorganic dielectric material.

In one or more twenty-first embodiments, further to the eighteenth through twentieth embodiments, the multichip composite device further comprises a structural member over integrated circuit die, wherein the first of the microchannels further extends through the structural member.

In one or more twenty-second embodiments, further to the eighteenth through twenty-first embodiments, a first lateral portion of the first of the microchannels within the inorganic dielectric material is exposed to the base die and a second lateral portion of the first of the microchannels extends through the structural member over the integrated circuit die.

In one or more twenty-third embodiments, a system comprises a multichip composite device according to any of the preceding embodiments, a power supply coupled to the multichip composite device and/or a thermal solution coupled to the multichip composite device.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A multi-chip composite device, comprising:
a base die having through vias extending from a first side to a second side, the through vias coupled to interconnects below the second side of the base die;
an integrated circuit (IC) die over and coupled to the first side of the base die;
a dummy die over and coupled to the first side of the base die, the dummy die laterally spaced apart from the IC die;
a dielectric material along a side of the dummy die opposite the IC die; and
a handle die over and coupled to the IC die and the dummy die, the handle die extending laterally beyond the side of the dummy die.

2. The multi-chip composite device of claim 1, wherein the dielectric material is laterally between the dummy die and the IC die.

3. The multi-chip composite device of claim 1, wherein the handle die is coupled to the IC die and the dummy die by a bonding layer.

4. The multi-chip composite device of claim 1, wherein the base die is coupled to a substrate by the interconnects.

5. The multi-chip composite device of claim 1, wherein the dummy die comprises silicon.

6. The multi-chip composite device of claim 1, wherein the handle comprises silicon.

7. The multi-chip composite device of claim 1, wherein the handle die has a width greater than a combined with of the IC die and the dummy die.

8. The multi-chip composite device of claim 1, wherein the IC die extends laterally beyond the base die.

9. A multi-chip composite device, comprising:
a first die having through vias extending from a first side to a second side, the through vias coupled to interconnects below the second side of the first die;
a second die over and coupled to the first side of the first die, wherein the second die is an integrated circuit (IC) die;
a third die over and coupled to the first side of the first die, the third die laterally spaced apart from the second die, wherein the third die is not an IC die;
a dielectric material along a side of the third die opposite the second die; and
a fourth die over and coupled to the second and the third die, the fourth die extending laterally beyond the side of the third die, wherein the fourth die is not an IC die.

10. The multi-chip composite device of claim 9, wherein the dielectric material is laterally between the third die and the second die.

11. The multi-chip composite device of claim 9, wherein the fourth die is coupled to the second die and the third die by a bonding layer.

12. The multi-chip composite device of claim 9, wherein the first die is coupled to a substrate by the interconnects.

13. The multi-chip composite device of claim 9, wherein the third die comprises silicon, and wherein the fourth die comprises silicon.

14. The multi-chip composite device of claim 9, wherein the fourth die has a width greater than a combined with of the second die and the third die.

15. The multi-chip composite device of claim 9, wherein the second die extends laterally beyond the first die.

16. A method of fabricating a multi-chip composite device, the method comprising:
providing a base die having through vias extending from a first side to a second side, the through vias coupled to interconnects below the second side of the base die;
coupling an integrated circuit (IC) die to the first side of the base die;
coupling a dummy die to the first side of the base die, the dummy die laterally spaced apart from the IC die;
forming a dielectric material along a side of the dummy die opposite the IC die; and
providing a handle die over and coupled to the IC die and the dummy die, the handle die extending laterally beyond the side of the dummy die.

17. The method of claim 16, wherein the dielectric material is laterally between the dummy die and the IC die.

18. The method of claim 16, wherein the handle die is coupled to the IC die and the dummy die by a bonding layer.

19. The method of claim 16, wherein the base die is coupled to a substrate by the interconnects.

20. The method of claim 16, wherein the dummy die comprises silicon, and wherein the handle comprises silicon.

21. The method of claim 16, wherein the handle die has a width greater than a combined with of the IC die and the dummy die.

22. The method of claim 16, wherein the IC die extends laterally beyond the base die.
